(19) United States
(12) Patent Application Publication
(10) Pub. No.: US 2022/0209737 A1
(43) Pub. Date: Jun. 30, 2022

(54) BULK-ACOUSTIC WAVE RESONATOR AND METHOD FOR FABRICATING BULK-ACOUSTIC WAVE RESONATOR

(71) Applicant: SAMSUNG ELECTRO-MECHANICS CO., LTD., Suwon-si (KR)

(72) Inventors: Tae Kyung LEE, Suwon-si (KR); Jae Goon AUM, Suwon-si (KR)

(73) Assignee: SAMSUNG ELECTRO-MECHANICS CO., LTD., Suwon-si (KR)

(21) Appl. No.: 17/337,899

(22) Filed: Jun. 3, 2021

(30) Foreign Application Priority Data
Dec. 24, 2020 (KR) 10-2020-0182721

(51) Int. Cl. H03H 9/02; H03H 3/02; H03H 9/17

(52) U.S. Cl. CPC H03H 9/02031; H03H 3/02; H03H 9/176; H03H 9/175; H03H 9/173

(57) ABSTRACT

A bulk-acoustic wave resonator includes: a substrate; and a resonator including a first electrode, a piezoelectric layer, and a second electrode sequentially stacked on the substrate. The piezoelectric layer is formed of aluminum nitride (AlN) containing scandium (Sc), the content of scandium in the piezoelectric layer is 10 wt % to 25 wt %, and the piezoelectric layer has a leakage current density of 1 μA/cm2 or less.

### CROSS-REFERENCE TO RELATED APPLICATION(S)

This application claims the benefit under 35 USC 119(a) of Korean Patent Application No. 10-2020-0182721 filed on Dec. 24, 2020 in the Korean Intellectual Property Office, the entire disclosure of which is incorporated herein by reference for all purposes.

### BACKGROUND

### 1. Field

The following description relates to a bulk-acoustic wave resonator and a method for manufacturing a bulk-acoustic wave resonator.

### 2. Description of Background

In accordance with the trend for the miniaturization of wireless communication devices, the miniaturization of high frequency component technology has been actively demanded. For example, a bulk-acoustic wave (BAW) type filter using a semiconductor thin film wafer manufacturing technology may be used.

A bulk-acoustic resonator (BAW) is formed when a thin film type element, causing resonance by depositing a piezoelectric dielectric material on a silicon wafer, a semiconductor substrate, and using the piezoelectric characteristics thereof, is implemented as a filter.

Technological interest in 5G communications has been increasing, and the development of technologies that can be implemented in candidate bands is being actively undertaken.

However, in the case of 5G communications using a Sub 6 GHz (4 to 6 GHz) frequency band, since the bandwidth is increased and the communication distance is shortened, the strength or power of the signal of the bulk-acoustic wave resonator may be increased. In addition, as the frequency increases, losses occurring in the piezoelectric layer or the resonator may be increased.

Therefore, a bulk-acoustic wave resonator capable of maintaining stable characteristics even under high voltage/high power conditions is required.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

A bulk-wave acoustic resonator capable of maintaining stable characteristics even under high voltage/high power conditions and a method for manufacturing the same.

In one general aspect, a bulk-acoustic wave resonator includes: a substrate; and a resonator including a first electrode, a piezoelectric layer, and a second electrode sequentially stacked on the substrate, wherein the piezoelectric layer is composed of aluminum nitride (AlN) containing scandium (Sc), the content of scandium in the piezoelectric layer is 10 wt % to 25 wt %, and the piezoelectric layer has a leakage current density of 1 μA/cm2 or less.

The bulk-acoustic wave resonator may include an insertion layer partially disposed in the resonator between the piezoelectric layer and the first electrode, and the piezoelectric layer and the second electrode may both be at least partially raised by the insertion layer.

The resonator may include a central portion and an extension portion disposed along a circumference of the central portion, the insertion layer may be disposed only in the extension portion of the resonator, the insertion layer may include an inclined surface with an increasing thickness as a distance from the central portion increases, and the piezoelectric layer may include an inclined portion disposed on the inclined surface of the insertion layer.

In a cross-section cut to cross the resonator, an end of the second electrode may be disposed at a boundary between the central portion and the extension portion, or may be disposed on the inclined portion of the piezoelectric layer.

The piezoelectric layer may include a piezoelectric portion disposed in the central portion and an extended portion extending outwardly of the inclined portion, and the second electrode may include at least a portion disposed on the extended portion of the piezoelectric layer.

The bulk-acoustic wave resonator may include a Bragg reflective layer disposed below the resonator, the Bragg reflective layer may include a first reflective layer having a first acoustic impedance and a second reflective layer having a second acoustic impedance lower than the first acoustic impedance, and the first reflective layer and the second reflective layer may be alternately stacked.

The substrate may include a groove-shaped cavity formed on an upper surface thereof, and the resonator may be spaced apart from the substrate by a cavity.

A cavity may be disposed inside the substrate, and the cavity may be connected to an outside of the substrate through an opening disposed around the resonator.

In another general aspect, a method for manufacturing a bulk-acoustic wave resonator includes: forming a piezoelectric layer by forming an AlScN thin film and performing a rapid thermal annealing (RTA) process on the AlScN thin film such that the piezoelectric layer has a leakage current density of 1 μA/cm2 or less; and sequentially stacking a first electrode, the piezoelectric layer, and a second electrode on a substrate to form a resonator.

Forming the AlScN thin film may be performed through a sputtering process using aluminum-scandium (AlSc) as a target.

The RTA process may be performed at a temperature of 500° C. or higher.

The piezoelectric layer may contain 10 wt % to 25 wt % of scandium (Sc).

The method may include forming an insertion layer disposed between the piezoelectric layer and the first electrode, and at least a portion of the piezoelectric layer and the second electrode may both be raised by the insertion layer.

The insertion layer may include an inclined surface, and in a cross-section cut to cross the resonator, at least a portion of an end of the second electrode may be disposed to overlap the insertion layer.

The resonator may include a central portion and an extension portion disposed along a periphery of the central portion, and the end of the second electrode may be disposed in the extension portion.

Other features and aspects will be apparent from the following detailed description, the drawings, and the claims.

### BRIEF DESCRIPTION OF DRAWINGS

FIG. 1 is a plan view of an acoustic wave resonator according to an example.

FIG. 2 is a cross-sectional view taken along line I-I′ of FIG. 1.

FIG. 3 is a cross-sectional view taken along line II-II′ of FIG. 1.

FIG. 4 is a cross-sectional view taken along line III-III′ in FIG. 1.

FIG. 5 is a view illustrating measurement of leakage current density according to a scandium (Sc) content of a piezoelectric layer.

FIG. 6 is a graph created based on the leakage current characteristic of FIG. 5.

FIG. 7 is a graph measuring a leakage current according to an RTA process temperature.

FIG. 8 is a view illustrating the measurement of the leakage current density according to the scandium (Sc) content of the piezoelectric layer and an RTA process temperature.

FIG. 9 is a graph created based on the data of FIG. 8.

FIG. 10 is a graph measuring a characteristic of a filter using the bulk-acoustic wave resonator of FIG. 1.

FIG. 11 is a cross-sectional view schematically illustrating a bulk-acoustic wave resonator according to an example.

FIG. 12 is a cross-sectional view schematically illustrating a bulk-acoustic wave resonator according to an example.

FIG. 13 is a cross-sectional view schematically illustrating a bulk-acoustic wave resonator according to an example.

FIG. 14 is a cross-sectional view schematically illustrating a bulk-acoustic wave resonator according to an example.

FIG. 15 is a cross-sectional view schematically illustrating a bulk-acoustic wave resonator according to an example.

Throughout the drawings and the detailed description, the same reference numerals refer to the same elements. The drawings may not be to scale, and the relative size, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The drawings may not be to scale, and the relative sizes, proportions, and depiction of elements in the drawings may be exaggerated for clarity, illustration, and convenience.

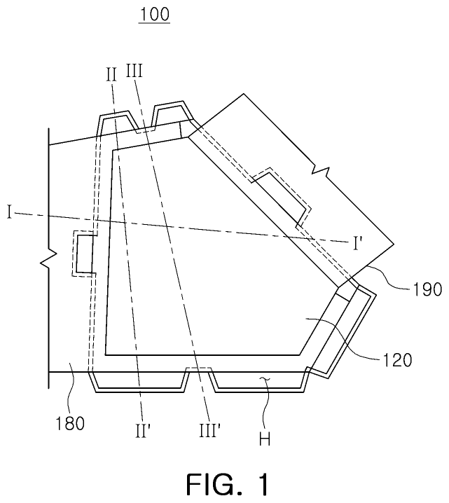

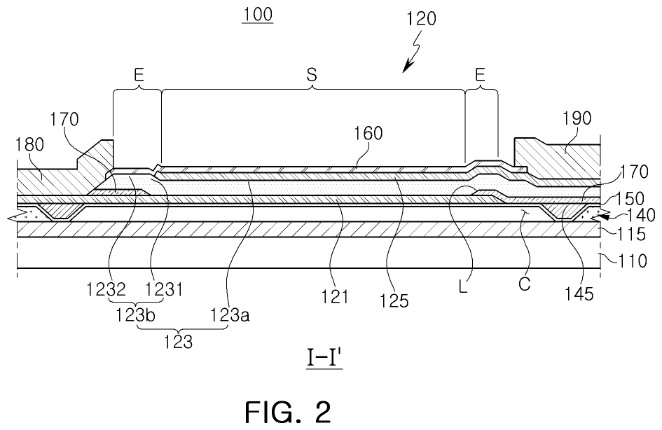

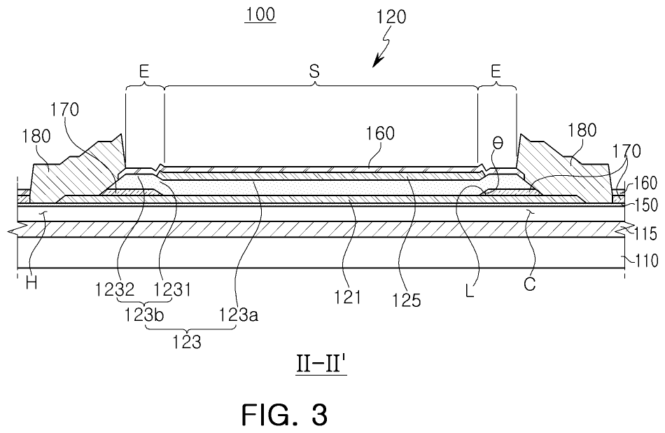

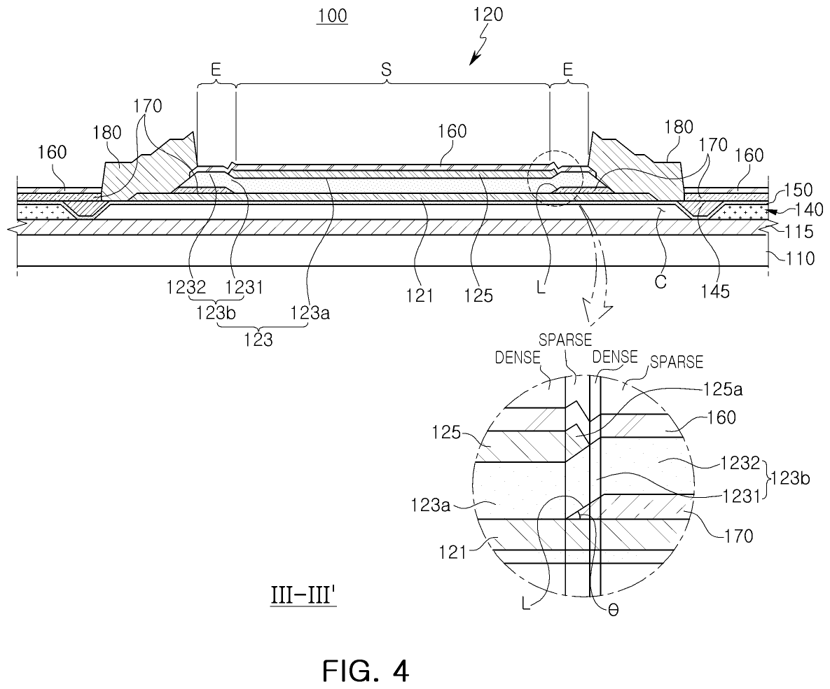

FIG. 1 is a plan view of a bulk-acoustic wave resonator according to an example, FIG. 2 is a cross-sectional view taken along line I-I′ of FIG. 1, FIG. 3 is a cross-sectional view taken along line II-II′ of FIG. 1, and FIG. 4 is a cross-sectional view taken along line III-III′ of FIG. 1.

Referring to FIGS. 1 to 4, an acoustic wave resonator 100 may be a bulk acoustic (BAW) resonator, and may include a substrate 110, a sacrificial layer 140, a resonator 120, and an insertion layer 170.

The substrate 110 may be a silicon substrate. For example, a silicon wafer may be used as the substrate 110, or a silicon on insulator (SOI) type substrate may be used.

An insulating layer 115 may be provided on an upper surface of the substrate 110 to electrically isolate the substrate 110 and the resonator 120. In addition, the insulating layer 115 prevents the substrate 110 from being etched by etching gas when a cavity C is formed in a process of manufacturing the acoustic-wave resonator.

In this case, the insulating layer 115 may be formed of at least one of silicon dioxide (SiO₂), silicon nitride (Si₃N₄), aluminum oxide (Al₂O₃), and aluminum nitride (AlN), and may be formed through any one process of chemical vapor deposition, RF magnetron sputtering, and evaporation.

The sacrificial layer 140 is formed on the insulating layer 115, and the cavity C and an etch-stop portion 145 are disposed in the sacrificial layer 140.

The cavity C is formed as an empty space, and may be formed by removing a portion of the sacrificial layer 140.

As the cavity C is formed in the sacrificial layer 140, the resonator 120 formed above the sacrificial layer 140 may be formed to be entirely flat.

The etch-stop portion 145 is disposed along a boundary of the cavity C. The etch-stop portion 145 is provided to prevent etching from being performed beyond a cavity region in a process of forming the cavity C.

A membrane layer 150 is formed on the sacrificial layer 140, and forms an upper surface of the cavity C. Therefore, the membrane layer 150 is also formed of a material that is not easily removed in the process of forming the cavity C.

For example, when a halide-based etching gas such as fluorine (F), chlorine (Cl), or the like is used to remove a portion (e.g., a cavity region) of the sacrificial layer 140, the membrane layer 150 may be formed of a material having low reactivity with the etching gas. In this case, the membrane layer 150 may include at least one of silicon dioxide (SiO₂) and silicon nitride (Si₃N₄).

The membrane layer 150 may be formed of a dielectric layer containing at least one of magnesium oxide (MgO), zirconium oxide (ZrO₂), aluminum nitride (AlN), lead zirconate titanate (PZT), gallium arsenide (GaAs), hafnium oxide (HfO₂), and aluminum oxide (Al₂O₃), titanium oxide (TiO₂), and zinc oxide (ZnO), or a metal layer containing at least one of aluminum (Al), nickel (Ni), chromium (Cr), platinum (Pt), gallium (Ga), and hafnium (Hf).

The resonator 120 includes a first electrode 121, a piezoelectric layer 123, and a second electrode 125. The resonator 120 is configured such that the first electrode 121, the piezoelectric layer 123, and the second electrode 125 are stacked in order from a bottom (from a substrate side). Therefore, the piezoelectric layer 123 in the resonator 120 is disposed between the first electrode 121 and the second electrode 125.

Since the resonator 120 is formed on the membrane layer 150, the membrane layer 150, the first electrode 121, the piezoelectric layer 123, and the second electrode 125 are sequentially stacked on the substrate 110, to form the resonator 120.

The resonator 120 may resonate the piezoelectric layer 123 according to signals applied to the first electrode 121 and the second electrode 125 to generate a resonance frequency and an anti-resonance frequency.

The resonator 120 may be divided into a central portion S in which the first electrode 121, the piezoelectric layer 123, and the second electrode 125 are stacked to be substantially flat, and an extension portion E in which the insertion layer 170 is interposed between the first electrode 121 and the piezoelectric layer 123.

The central portion S is a region disposed in a center of the resonator 120, and the extension portion E is a region disposed along a periphery of the central portion S. Therefore, the extension portion E is a region extended from the central portion S externally, and refers to a region formed to have a continuous annular shape along the periphery of the central portion S. However, if necessary, the extension portion E may be configured to have a discontinuous annular shape, in which some regions are disconnected.

Accordingly, as shown in FIG. 2, in the cross-section of the resonator 120 cut so as to cross the central portion S, the extension portion E is disposed at both ends of the central portion S, respectively. The insertion layer 170 is disposed on both sides of the central portion S of the extension portion E disposed at both ends of the central portion S.

The insertion layer 170 has an inclined surface L, which has a thickness that increases as a distance from the central portion S increases.

In the extension portion E, the piezoelectric layer 123 and the second electrode 125 are disposed on the insertion layer 170. Therefore, the piezoelectric layer 123 and the second electrode 125 located in the extension portion E have an inclined surface along the shape of the insertion layer 170.

It is described herein that the extension portion E is included in the resonator 120, and accordingly, resonance may also occur in the extension portion E. However, the configuration is not limited thereto, and resonance may not occur in the extension portion E depending on the structure of the extension portion E, and resonance may occur only in the central portion S.

The first electrode 121 and the second electrode 125 may be formed of a conductor, for example, may be formed of gold, molybdenum, ruthenium, iridium, aluminum, platinum, titanium, tungsten, palladium, tantalum, chromium, nickel, or a metal containing at least one thereof, but is not limited to such materials.

In the resonator 120, the first electrode 121 is formed to have a larger area than the second electrode 125, and a first metal layer 180 is disposed along an outer periphery of the first electrode 121 on the first electrode 121. Therefore, the first metal layer 180 may be disposed to be spaced apart from the second electrode 125 by a predetermined distance, and may be disposed in a form surrounding the resonator 120.

Since the first electrode 121 is disposed on the membrane layer 150, the first electrode 121 is formed to be entirely flat. On the other hand, since the second electrode 125 is disposed on the piezoelectric layer 123, curving may be formed corresponding to the shape of the piezoelectric layer 123.

The first electrode 121 may be used as any one of an input electrode and an output electrode for inputting and outputting an electrical signal such as a radio frequency (RF) signal.

The second electrode 125 is entirely disposed in the central portion S, and partially disposed in the extension portion E. Accordingly, the second electrode 125 may be divided into a portion disposed on a piezoelectric portion 123a of the piezoelectric layer 123, and a portion disposed on a curved portion 123b of the piezoelectric layer 123.

More specifically, in the present example, the second electrode 125 is disposed to cover an entirety of the piezoelectric portion 123a and a portion of an inclined portion 1231 of the curved portion 123b of the piezoelectric layer 123. Accordingly, the second electrode (125a in FIG. 4) disposed in the extension portion E is formed to have a smaller area than an inclined surface of the inclined portion 1231, and the second electrode 125 in the resonator 120 is formed to have a smaller area than the piezoelectric layer 123.

Accordingly, as shown in FIG. 2, in a cross-section of the resonator 120 cut so as to cross the central portion S, an end of the second electrode 125 is disposed in the extension portion E. In addition, at least a portion of the end of the second electrode 125 disposed in the extension portion E is disposed to overlap the insertion layer 170. Here, ‘overlap’ means that when the second electrode 125 is projected on a plane on which the insertion layer 170 is disposed, a shape of the second electrode 125 projected on the plane overlaps the insertion layer 170.

The second electrode 125 may be used as any one of an input electrode and an output electrode for inputting and outputting an electrical signal such as a radio frequency (RF) signal, or the like. For example, when the first electrode 121 is used as the input electrode, the second electrode 125 may be used as the output electrode, and when the first electrode 121 is used as the output electrode, the second electrode 125 may be used as the input electrode.

As shown in FIG. 4, when the end of the second electrode 125 is positioned on the inclined portion 1231 of the piezoelectric layer 123, since a local structure of an acoustic impedance of the resonator 120 is formed in a sparse/dense/sparse/dense structure from the central portion S, a reflective interface reflecting a lateral wave inwardly of the resonator 120 is increased. Therefore, since most lateral waves could not flow outwardly of the resonator 120, and are reflected and then flow to an interior of the resonator 120, the performance of the acoustic resonator may be improved.

The piezoelectric layer 123 is a portion converting electrical energy into mechanical energy in a form of elastic waves through a piezoelectric effect, and is formed on the first electrode 121 and the insertion layer 170.

As a material of the piezoelectric layer 123, zinc oxide (ZnO), aluminum nitride (AlN), doped aluminum nitride, lead zirconate titanate, quartz, and the like can be selectively used. In the case of doped aluminum nitride, a rare earth metal, a transition metal, or an alkaline earth metal may be further included. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). In addition, the alkaline earth metal may include magnesium (Mg).

In order to improve piezoelectric properties, when a content of elements doped with aluminum nitride (AlN) is less than 0.1 at %, a piezoelectric property higher than that of aluminum nitride (AlN) cannot be realized. When the content of the elements exceeds 30 at %, it is difficult to fabricate and control the composition for deposition, such that uneven crystalline phases may be formed.

Therefore, in the present example, the content of elements doped with aluminum nitride (AlN) may be in a range of 0.1 to 30 at %.

In the present example, the piezoelectric layer is doped with scandium (Sc) in aluminum nitride (AlN). In this case, a piezoelectric constant may be increased to increase Kt² of the acoustic resonator.

The piezoelectric layer 123 according to the present example includes the piezoelectric portion 123a disposed in the central portion S and the curved portion 123b disposed in the extension portion E.

The piezoelectric portion 123a is a portion directly stacked on the upper surface of the first electrode 121. Therefore, the piezoelectric portion 123a is interposed between the first electrode 121 and the second electrode 125 and formed as a flat shape, together with the first electrode 121 and the second electrode 125.

The curved portion 123b may be a region extending from the piezoelectric portion 123a externally and positioned in the extension portion E.

The curved portion 123b is disposed on the insertion layer 170, and is formed in a shape in which the upper surface thereof is raised along the shape of the insertion layer 170. Accordingly, the piezoelectric layer 123 is curved at a boundary between the piezoelectric portion 123a and the curved portion 123b, and the curved portion 123b is raised corresponding to the thickness and shape of the insertion layer 170.

The curved portion 123b may be divided into the inclined portion 1231 and an extended portion 1232. The inclined portion 1231 refers to a portion formed to be inclined along the inclined surface L of the insertion layer 170. The extended portion 1232 is a portion extending from the inclined portion 1231 externally. The inclined portion 1231 is formed parallel to the inclined surface L of the insertion layer 170, and an inclination angle of the inclined portion 1231 may be formed to be the same as an inclination angle of the inclined surface L of the insertion layer 170.

The insertion layer 170 is disposed along a surface formed by the membrane layer 150, the first electrode 121, and the etch-stop portion 145. Therefore, the insertion layer 170 is partially disposed in the resonator 120, and is disposed between the first electrode 121 and the piezoelectric layer 123.

The insertion layer 170 is disposed around the central portion S to support the curved portion 123b of the piezoelectric layer 123. Accordingly, the curved portion 123b of the piezoelectric layer 123 may be divided into the inclined portion 1231 and the extension portion 1232 according to the shape of the insertion layer 170.

In the present example, the insertion layer 170 is disposed in a region except for the central portion S. For example, the insertion layer 170 may be disposed on the substrate 110 in an entire region except for the central portion S, or in some regions.

The insertion layer 170 is formed to have a thickness that increases as a distance from the central portion S increases. Thereby, the insertion layer 170 is formed with the inclined surface L having a constant inclination angle θ of the side surface disposed adjacent to the central portion S.

When the inclination angle θ of the side surface of the insertion layer 170 is formed to be narrower than 5°, in order to manufacture the side surface, since the thickness of the insertion layer 170 should be formed to be very thin or an area of the inclined surface L should be formed to be excessively wide, it is practically difficult to be implemented.

When the inclination angle θ of the side surface of the insertion layer 170 is formed to be wider than 70°, the inclination angle of the piezoelectric layer 123 or the second electrode 125 stacked on the insertion layer 170 is also formed to be wider than 70°. In this case, since the piezoelectric layer 123 or the second electrode 125 stacked on the inclined surface L is excessively curved, cracks may be generated in the curved portion.

Therefore, in the present example, the inclination angle θ of the inclined surface L is formed to be within a range of 5° or more and 70° or less.

The inclined portion 1231 of the piezoelectric layer 123 is formed along the inclined surface L of the insertion layer 170, and thus is formed to have the same inclination angle as the inclined surface L of the insertion layer 170. Therefore, the inclination angle of the inclined portion 1231 is also formed to be within a range of 5° or more and 70° or less, similarly to the inclined surface L of the insertion layer 170. The configuration may also be equally applied to the second electrode 125 stacked on the inclined surface L of the insertion layer 170.

The insertion layer 170 may be formed of a dielectric material such as silicon oxide (SiO₂), nitride aluminum (AlN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), and zinc oxide (ZnO), but is not limited to these materials.

The insertion layer 170 may be implemented with a metal material. When the bulk-acoustic wave resonator is used for 5G communications, heat generated from the resonator 120 needs to be smoothly discharged because a lot of heat is generated from the resonator. To this end, the insertion layer 170 may be formed of an aluminum alloy material containing scandium (Sc).

Further, the insertion layer 170 may be formed of a SiO₂ thin film injected with nitrogen (N) or fluorine (F).

The resonator 120 is disposed to be spaced apart from the substrate 110 through the cavity C, which is formed as an empty space.

The cavity C may be formed by removing a portion of the sacrificial layer 140 by supplying an etching gas (or an etching solution) to an inlet hole (inlet hole H in FIG. 1) in a process of manufacturing an acoustic resonator.

A protective layer 160 is disposed along the surface of the acoustic resonator 100 to protect the acoustic resonator 100 from the outside. The protective layer 160 may be disposed along a surface formed by the second electrode 125 and the curved portion 123b of the piezoelectric layer 123.

The first electrode 121 and the second electrode 125 may extend outwardly of the resonator 120. The first metal layer 180 and a second metal layer 190 may be disposed on the upper surface of the extended portion, respectively.

The first metal layer 180 and the second metal layer 190 may be formed of any one material among gold (Au), a gold-tin (Au—Sn) alloy, copper (Cu), a copper-tin (Cu—Sn) alloy, and aluminum (Al), or an aluminum alloy. Here, the aluminum alloy may be an aluminum-germanium (Al—Ge) alloy or an aluminum-scandium (Al—Sc) alloy.

The first metal layer 180 and the second metal layer 190 may function as a connection wiring electrically connecting the electrodes 121 and 125 of the acoustic resonator 100 on the substrate 110 and electrodes of other acoustic resonators disposed adjacent to each other.

The first metal layer 180 penetrates the protective layer 160 and is bonded to the first electrode 121.

In the resonator 120, the first electrode 121 is formed to have a larger area than the second electrode 125, and the first metal layer 180 is formed on the peripheral portion of the first electrode 121.

Therefore, the first metal layer 180 is disposed along the periphery of the resonator 120, and thus is disposed in a form surrounding the second electrode 125. However, the configuration is not limited thereto.

At least a portion of the protective layer 160 located on the resonator 120 is disposed to contact the first metal layer 180 and the second metal layer 190. The first metal layer 180 and the second metal layer 190 are formed of a metal material having high thermal conductivity and have a large volume, such that the first metal layer 180 and the second metal layer 190 have a high heat dissipation effect.

Therefore, the protective layer 160 is connected to the first metal layer 180 and the second metal layer 190, such that heat generated in the piezoelectric layer 123 may be quickly transmitted to the first metal layer 180 and the second metal layer 190 via the protective layer 160.

In the present example, at least a portion of the protective layer 160 is disposed below the first metal layer 180 and the second metal layer 190. Specifically, the protective layer 160 is disposed between the first metal layer 180 and the piezoelectric layer 123, and between the second metal layer 190, the second electrode 125, and the piezoelectric layer 123, respectively.

In the bulk-acoustic wave resonator 100, the piezoelectric layer 123 may be formed by doping aluminum nitride (AlN) with an element such as scandium (Sc) to increase a bandwidth of the resonator 120.

As described above, when the piezoelectric layer 123 is formed by doping aluminum nitride (AlN) with scandium (Sc), a piezoelectric constant thereof may be increased to increase Kt² of the acoustic resonator.

In order for the bulk-acoustic wave resonator to be used for 5G communications, it must have a high piezoelectric constant for the piezoelectric layer 123 to be smoothly operated at a corresponding frequency.

As a result of the measurement, it was found that in order to be used for 5G communications, the piezoelectric layer 123 should contain 10 wt % or more of scandium (Sc) in aluminum nitride (AlN). Accordingly, in the present example, the piezoelectric layer 123 may be formed of an AlScN material having a scandium (Sc) content of 10 wt % or more.

Here, the scandium (Sc) content is defined based on a weight of aluminum and scandium. For example, when the scandium (Sc) content is 10 wt %, which means the weight of scandium is 10 g, the total weight of aluminum and scandium is 100 g.

The piezoelectric layer 123 may be formed through a sputtering process, and a sputtering target used in the sputtering process, which is an aluminum-scandium (AlSc) target, may be manufactured through a melting method melting and then curing aluminum and scandium.

However, when an aluminum-scandium (AlSc) target having a scandium (Sc) content of 40 wt % or more, is manufactured, since an Al₂Sc phase as well as an Al₃Sc phase is formed, there is a problem that the target is easily damaged during a handling process of the target due to the fragile Al₂Sc phase. In addition, in the sputtering process, when high power of 1 kW or more is applied to a sputtering target mounted on a sputtering device in the sputtering process, a crack may occur in the sputtering target. Accordingly, in the present example, the piezoelectric layer 123 may be formed of an AlScN material having a scandium (Sc) content of 10 wt % to 40 wt %.

An analysis of a content of Sc element in an AlScN thin film can be confirmed by an energy dispersive X-ray spectroscopy (EDS) analysis of a scanning electron microscopy (SEM) and a transmission electron microscope (TEM), but is not limited thereto, and it may also be confirmed using an X-ray photoelectron spectroscopy (XPS) analysis.

When the piezoelectric layer 123 is composed of aluminum nitride (AlN) containing scandium (Sc), it was also measured that leakage current generated in the piezoelectric layer 123 increases as the content of scandium (Sc) increases.

The leakage current density represents a leakage current per unit area, and the leakage current generated in the piezoelectric layer 123 is a major factor. Occurrence of the leakage current in the piezoelectric layer 123 can be attributed to two causes: a Schottky emission with an electrode interface and a Poole-Frenkel emission generated inside the piezoelectric layer.

In addition, the leakage current may increase even when an orientation from a hexagonal closed packed (HCP) crystal structure, a crystal structure of an AlScN piezoelectric layer, to the (0002) crystal plane is poor. In the AlScN piezoelectric layer 123, as scandium (Sc) atoms, greater than aluminum (Al) atoms are substituted for aluminum (Al) sites, deformation may occur in an AlScN unit lattice. Thereby, when defect sites such as voids, dislocations, or the like in the piezoelectric layer 123 increase, the leakage current may increase.

When the content of scandium (Sc) increases in the piezoelectric layer 123, defect sites may increase in the piezoelectric layer 123, and such defect sites may act as a factor of abnormal growth of the piezoelectric layer 123. Therefore, when the piezoelectric layer 123 is formed of an AlScN material, not only the leakage current density but also the content of scandium (Sc) in the piezoelectric layer 123 must be considered.

In addition, as the frequency of the bulk-acoustic wave resonator for 5G communications increases, the thickness of the resonator 120 must be reduced. Accordingly, in the bulk-acoustic wave resonator of the present example, the piezoelectric layer 123 may have a thickness of 5000 Å or less. However, when the thickness of the piezoelectric layer 123 decreases, an amount of leakage current leaking from the piezoelectric layer 123 tends to increase.

When the above-described leakage current is large, the breakdown voltage of the piezoelectric layer 123 may be lowered, so that the piezoelectric layer may be easily damaged under high voltage/high power environments. Accordingly, the bulk-acoustic wave resonator of the present example is configured to satisfy the following Equations 1 and 2 with respect to the leakage current and the scandium (Sc) content of the piezoelectric layer so as to stably operate under high voltage/high power environments.

Leakage current characteristic<20 Equation 1

Leakage current characteristic=Leakage current density (μA/cm²)×Scandium (Sc) content (wt %) Equation 2

In equations 1 and 2, the leakage current density means a leakage current density of the piezoelectric layer 123, and the scandium (Sc) content is a content of scandium (Sc) contained in the piezoelectric layer 123. In addition, the above-described leakage current characteristic is a factor defining the performance of a bulk-acoustic wave resonator that can be used as a filter in 5G communications.

When the bulk-acoustic wave resonator of the present example has a leakage current characteristic of less than 20, the leakage current density of the piezoelectric layer 123 has a magnitude similar to that of pure aluminum nitride.

Accordingly, since losses in the piezoelectric layer 123 are minimized, the bulk-acoustic wave resonator can provide an optimal performance as a filter for 5G communications.

On the other hand, when the leakage current characteristic is 20 or more, the leakage current may be excessively increased (e.g., 2 μA/cm² or more), so that a breakdown voltage of the piezoelectric layer may be very low, or the scandium (Sc) content may be excessive (for example, 40 wt % or more), so that abnormal growth in the piezoelectric layer may increase, and accordingly, since the characteristics of the bulk-acoustic wave resonator are deteriorated, it is difficult to secure the performance as the above-described filter.

Accordingly, the bulk-acoustic wave resonator of the present example is configured to satisfy Equation 1 described above by minimizing the leakage current density in the piezoelectric layer 123 formed of an AlScN material.

In order to minimize the leakage current in the piezoelectric layer 123, the bulk-acoustic wave resonator of the present example may perform a heat treatment of the piezoelectric layer 123 during manufacturing process.

The heat treatment of the piezoelectric layer 123 may be performed through a rapid thermal annealing (RTA) process. In the present example, the RTA process may be performed at a temperature of 500° C. or higher for 1 minute to 30 minutes. However, the process is not limited thereto.

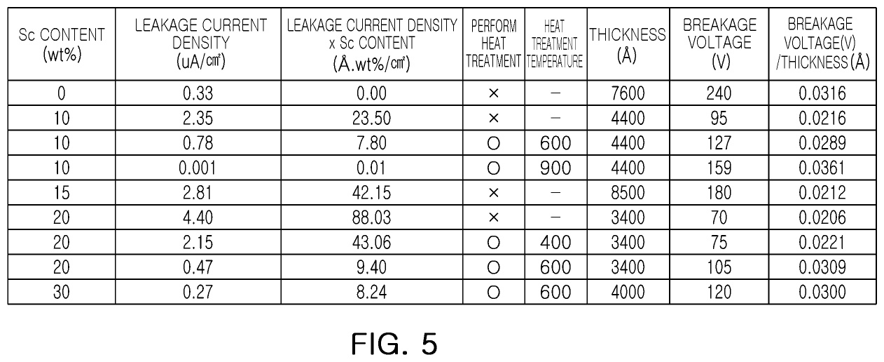

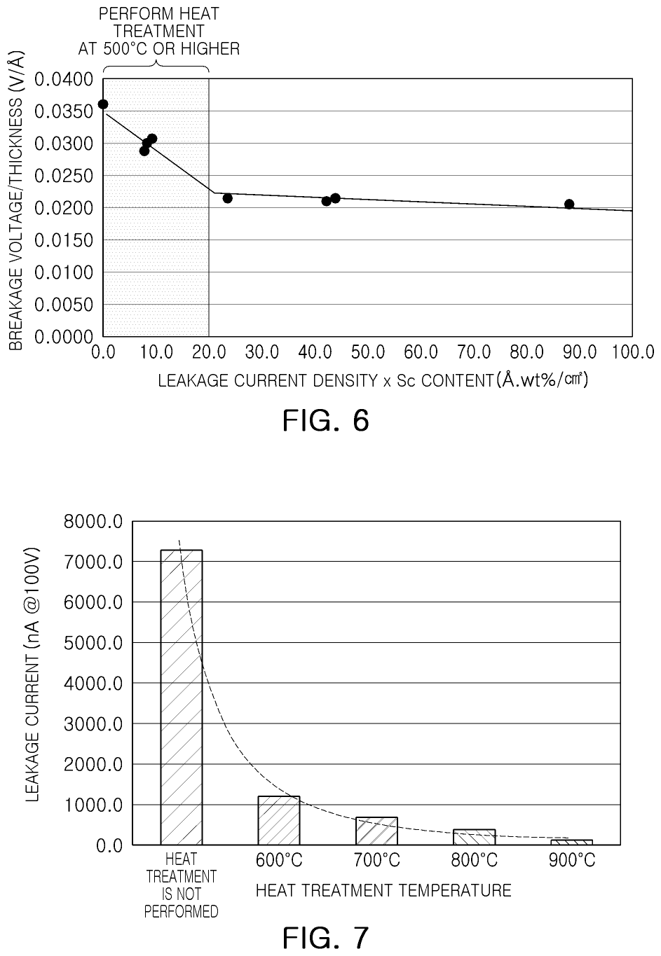

FIG. 5 is a view illustrating measurement of leakage current density according to a scandium (Sc) content of the piezoelectric layer, and FIG. 6 is a graph created based on the leakage current characteristic of FIG. 5. Here, the leakage current density was measured while forming the same electric field of 0.1V/nm between a first electrode 121 and a second electrode 125.

Referring to FIG. 5, in the case of pure aluminum, the piezoelectric layer of the present example having a content of scandium (Sc) of 0, it was shown that the leakage current density is measured to be 0.33 μA/cm², and when the piezoelectric layer contains scandium (Sc), the leakage current density is significantly increased, such as 2.35 μA/cm², 2.81 μA/cm², 4.40 μA/cm², or the like.

On the other hand, when the heat treatment was performed after doping aluminum nitride (AlN) with scandium (Sc), the leakage current densities were 0.78 μA/cm², 0.001 μA/cm², 0.47 μA/cm², 0.27 μA/cm², or the like. Therefore, when the heat treatment was performed, a leakage current density, similar to that of pure aluminum nitride (AlN) without scandium (Sc) was measured.

In addition, as shown in FIG. 6, it was shown that all of the piezoelectric layers not subjected to heat treatment had a leakage current characteristic of 20 or more.

As described above, when the leakage current density in the piezoelectric layer is large, the piezoelectric layer may be easily damaged in high voltage/high power environments. Accordingly, in order to prevent this and to use the bulk-acoustic wave resonator as a filter in 5G communication, the bulk-acoustic wave resonator of the present example may include a piezoelectric layer having a leakage current characteristic of less than 20.

When a heat treatment was performed on aluminum nitride (AlN) containing scandium (Sc), the leakage current characteristics were all measured to be less than 10. Therefore, based on the data measured by performing the heat treatment, the bulk-acoustic wave resonator of the present example can also define the leakage current characteristic of the piezoelectric layer to be less than 10.

In addition, referring to FIG. 5, all of the piezoelectric layers to which the heat treatment was not performed had a leakage current density of 2 μA/cm² or more. Therefore, it can be seen that the leakage current characteristic is 20 or less in a range of the leakage current density of 2 μA/cm² or less. Accordingly, in the present example, the leakage current density of the piezoelectric layer may be defined as 2 μA/cm² or less. The piezoelectric layers formed of an AlScN material subjected to heat treatment were all measured to have a leakage current density of 1 μA/cm² or less. Therefore, when only the piezoelectric layer on which the heat treatment has been performed is considered, it is also possible to define the leakage current density of the piezoelectric layer to be 1 μA/cm² or less.

In the present example, when the piezoelectric layer contains scandium (Sc), a breakdown voltage of the piezoelectric layer may be 100V or more. From this, it can be seen that when the piezoelectric layer contains scandium (Sc) and the breakdown voltage is 100V or more, the piezoelectric layer of the present example may be used as a filter. In addition, with respect to a thickness of the piezoelectric layer, when the leakage current characteristic is 20 or less, a ratio (V/Å) of the breakdown voltage of the piezoelectric layer to the thickness of the piezoelectric layer was all measured to be 0.025 or more. Accordingly, in the present example, a piezoelectric layer may be formed such that a ratio (V/Å) of a breakdown voltage of the piezoelectric layer to the thickness of the piezoelectric layer is 0.025 or more.

In the piezoelectric layer, leakage current characteristics may vary depending on the heat treatment temperature.

FIG. 7 is a graph measuring a leakage current according to an RTA process temperature, an AlScN piezoelectric layer containing 10 wt % of scandium (Sc) was formed to have a thickness of 4000 Å, and a leakage current was measured after a heat treatment is performed at various temperatures.

Referring to FIG. 7, it can be seen that the leakage current is significantly reduced when the heat treatment is performed compared to when the heat treatment process is not performed, and it can be seen that the leakage current is further reduced as a heat treatment temperature increases.

Accordingly, even if the scandium (Sc) content is increased, a piezoelectric layer satisfying Equation 1 can be manufactured by optimizing the heat treatment temperature.

In addition, in the bulk-acoustic wave resonator of the present example, an RTA process may be performed at a temperature of 500° C. or higher.

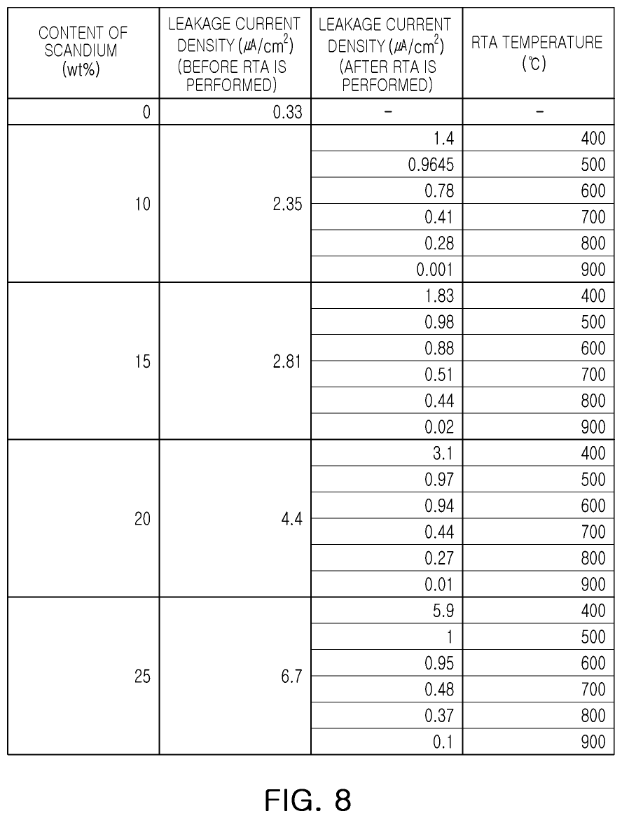

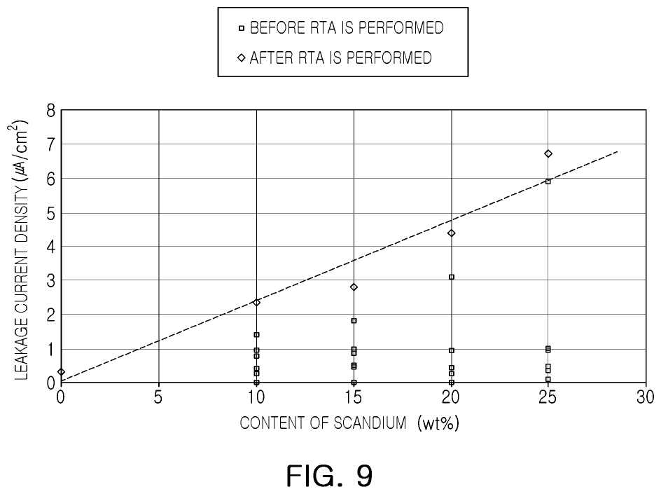

FIG. 8 is a view illustrating measurement of leakage current density according to a scandium (Sc) content of a piezoelectric layer and an RTA process temperature, and FIG. 9 is a graph created based on data of FIG. 8.

The data in FIG. 8 is data measured by applying a value obtained by multiplying a thickness of the piezoelectric layer (Å) by 1/100 to the piezoelectric layer 123 as a voltage (V). For example, when the thickness of the piezoelectric layer is 5000 Å, a voltage of 50 V, which is a value obtained by multiplying 5000 by 1/100, was applied to the piezoelectric layer to measure the leakage current density. Similarly, when the thickness of the piezoelectric layer is 4400 Å, a voltage of 44V, which is a value of 4400 by multiplying by 1/100, was applied to the piezoelectric layer to measure the leakage current density.

Referring to FIGS. 8 and 9, it can be seen that the bulk-acoustic wave resonator of the present example has a leakage current density of 1 μA/cm² or less of the piezoelectric layer when the RTA process temperature is 500° C. or higher. On the other hand, when the RTA process temperature is lower than 500° C., for example, at a process temperature of 400° C., the leakage current density of the piezoelectric layer was all measured to significantly exceed 1 μA/cm².

Even if a content of scandium (Sc) contained in the piezoelectric layer varies, it can be seen that the leakage current density of the piezoelectric layer is maintained at 1 μA/cm² or less when the RTA process temperature is 500° C. or higher.

Accordingly, in the present example, the RTA process temperature may be defined as 500° C. or higher. Meanwhile, as shown in FIG. 8, it can be seen that as the content of scandium (Sc) contained in the piezoelectric layer increases, the leakage current density generally increases. When the content of scandium (Sc) is 25 wt % and the RTA process temperature is 500° C., the leakage current density was measured to be 1 μA/cm2.

Therefore, when the content of scandium (Sc) exceeds 25 wt %, the leakage current density may exceed 1 μA/cm² even if the RTA process is performed at a process temperature of 500° C.

Accordingly, with reference to FIGS. 8 and 9, the bulk-acoustic wave resonator according to the present example may be defined as a bulk-acoustic wave resonator manufactured at an RTA process temperature of 500° C. or higher with a content of scandium (Sc) of 25 wt % or less.

As described above, in order for the bulk-acoustic wave resonator to be used for 5G communication, since the piezoelectric layer 123 must contain 10 wt % or more of scandium (Sc) in aluminum nitride (AlN), the piezoelectric layer 123 may be formed of an AlScN material having a scandium (Sc) content of 10 wt % or more and 25 wt % or less.

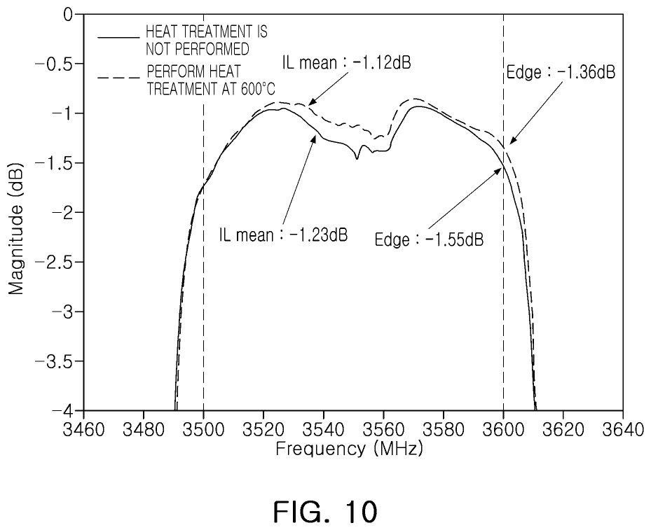

FIG. 10 is a graph measuring characteristics of a filter using the bulk-acoustic wave resonator of the present example, indicating insertion loss according to a frequency band. In addition, FIG. 8 illustrates both graphs of a bulk-acoustic wave resonator satisfying Equation 1 by performing heat treatment and a bulk-acoustic wave resonator not satisfying Equation 1 (a heat treatment is not performed).

Referring to FIG. 10, it was confirmed that in the bulk-acoustic wave resonator satisfying Equation 1, an insertion loss is improved from −1.23 dB to −1.12 dB, and a characteristic of 3.6 GHz side is improved from −1.55 dB to −1.36 dB, as compared to the bulk-acoustic wave resonator not satisfying Equation 1. Accordingly, it can be seen that when the piezoelectric layer is formed so that the leakage current characteristic satisfies Equation 1, losses in the piezoelectric layer are minimized, and thus the characteristics of the bulk-acoustic wave resonator filter are also improved.

The bulk-acoustic wave resonator 100 configured as described above may be formed in a such a manner that a first electrode 121, a piezoelectric layer 123, and a second electrode 125 are sequentially stacked to form a resonator 120, as shown in FIG. 2. In addition, the operation of forming the resonator 120 may include an operation of disposing an insertion layer 170 below the first electrode 121 or between the first electrode 121 and the piezoelectric layer 123. Accordingly, the insertion layer 170 may be disposed to be stacked on the first electrode 121, or the first electrode 121 may be disposed to be stacked on the insertion layer 170. The piezoelectric layer 123 and the second electrode 125 may be partially raised along a shape of the insertion layer 170, and the piezoelectric layer 123 may be formed on the first electrode 121 or the insertion layer 170. In addition, the operation of manufacturing the piezoelectric layer 123 may include an operation of forming an AlScN thin film containing scandium (Sc) through a sputtering process using an aluminum-scandium (AlSc) as a target, and an operation of performing an RTA process on the AlScN thin film to complete the piezoelectric layer 123.

The bulk-acoustic wave resonator 100 described above may have a piezoelectric layer having a leakage current characteristic of less than 20 since defects formed in the AlScN piezoelectric layer may be removed through the RTA process. Accordingly, even if the piezoelectric layer contains scandium (Sc), a leakage current is generated at a level of pure aluminum nitride (AlN), so that Kt2 of the bulk-acoustic wave resonator may be increased, and at the same time, stable characteristics can be maintained even under high voltage/high power conditions.

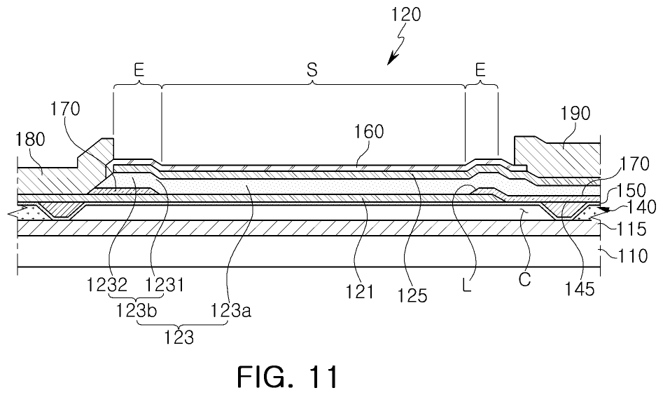

FIG. 11 is a schematic cross-sectional view of a bulk-acoustic wave resonator according to another example.

In the bulk-acoustic wave resonator illustrated in FIG. 11, a second electrode 125 may be disposed on an entire upper surface of the piezoelectric layer 123 in the resonator 120. Accordingly, at least a portion of the second electrode 125 may be formed on not only an inclined portion 1231 of the piezoelectric layer 123 but also an extension portion 1232. In addition, in a cross-section of the resonator 120 cut to cross the central portion S, an end portion of the second electrode 125 may be disposed on the extended portion 1232.

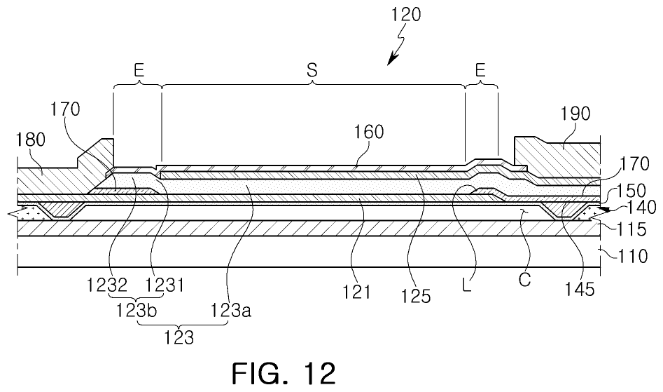

FIG. 12 is a schematic cross-sectional view of a bulk-acoustic wave resonator according to another example.

Referring to FIG. 12, in the bulk-acoustic wave resonator, in a cross-section of the resonator 120 cut to cross the central portion S, an end portion of the second electrode 125 is only on an upper surface of a piezoelectric portion 123a of the piezoelectric layer 123, and is not formed on a curved portion 123b. Accordingly, the end of the second electrode 125 may be disposed along a boundary between the piezoelectric portion 123a and the inclined portion 1231.

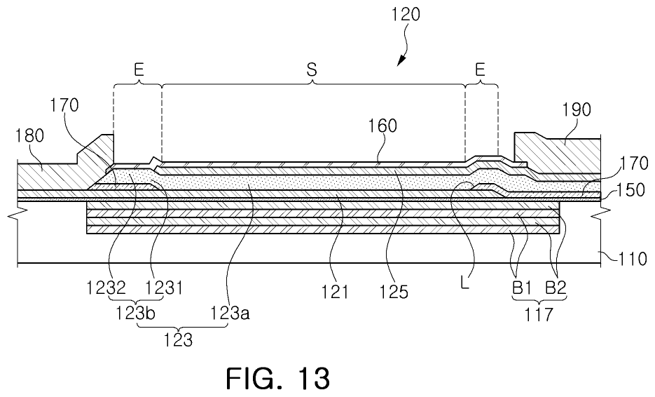

FIG. 13 is a schematic cross-sectional view of a bulk-acoustic wave resonator according to another example.

Referring to FIG. 13, the bulk-acoustic wave resonator is formed similarly to the bulk-acoustic wave resonator shown in FIG. 2, but does not have a cavity (C in FIG. 2), and includes a Bragg reflective layer 117. The Bragg reflective layer 117 may be disposed in the substrate 110, and may be formed in such a manner that a first reflective layer B1 having a high acoustic impedance and a second reflective layer having a low acoustic impedance are alternately stacked below the resonator 120. In this case, thicknesses of the first reflective layer B1 and the second reflective layer B2 may be defined according to a specific wavelength, so that acoustic waves are reflected in a vertical direction toward the resonator 120 to block the acoustic waves from flowing out to the lower side of the substrate 110. To this end, the first reflective layer B1 may be formed of a material having a higher density than the second reflective layer B2. For example, the first reflective layer B1 may be formed using a conductive material such as molybdenum (Mo) or an alloy thereof. However, the material is not limited thereto, and may include ruthenium (Ru), tungsten (W), iridium (Ir), platinum (Pt), copper (Cu), aluminum (Al), titanium (Ti), tantalum (Ta), nickel (Ni), chromium (Cr), and the like. The second reflective layer B2 may be formed using a material having a lower density than the first reflective layer B1, for example, may be formed of a material containing any one of silicon nitride (Si₃N₄), silicon oxide (SiO₂), magnesium oxide (MgO), zirconium oxide (ZrO₂), and nitride aluminum (AlN), lead zirconate titanate (PZT), gallium arsenide (GaAs), hafnium oxide (HfO₂), aluminum oxide (Al₂O₃), titanium oxide (TiO₂), and zinc oxide (ZnO), but is not limited to these materials.

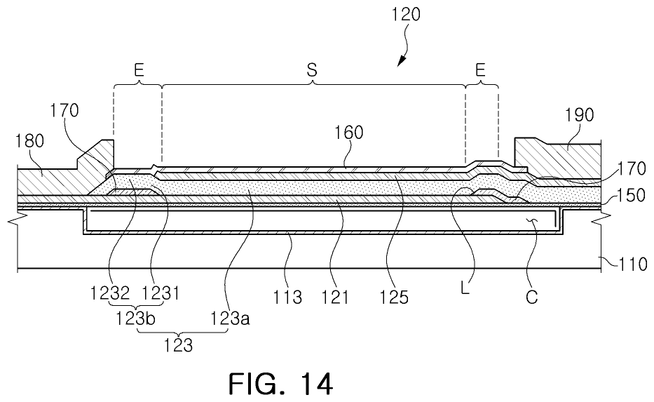

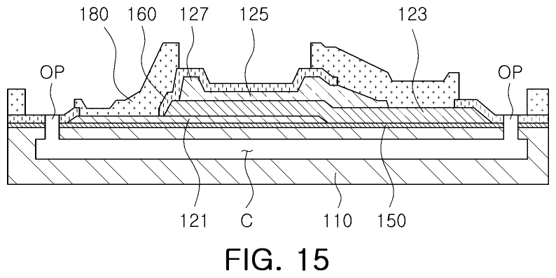

FIG. 14 is a schematic cross-sectional view of a bulk-acoustic wave resonator according to another example.

Referring to FIG. 14, the bulk-acoustic wave resonator is formed similarly to the bulk-acoustic wave resonator shown in FIG. 2, and a cavity is not formed above a substrate 110, but a cavity C is formed by partially removing the substrate 110. The cavity C of the present example may be formed in groove form by partially etching the upper surface of the substrate 110. The substrate 110 may be etched by using dry etching or wet etching. A barrier layer 113 may be formed on the inner surface of the cavity C. The barrier layer may protect the substrate 110 from an etching solution used in the process of forming the resonator 120. The barrier layer 113 may be formed of a dielectric layer such as AIN or SiO₂, but is not limited to these materials, and various materials may be used as long as the substrate 110 can be protected from the etching solution.

FIG. 15 is a schematic cross-sectional view of a bulk-acoustic wave resonator according to another example.

Referring to FIG. 15, in the bulk-acoustic wave resonator according to the present embodiment, a cavity is not formed above a substrate 110, but a cavity C is formed by partially removing an inside of the substrate 110. The cavity C of the present example may be formed in a form in which the inside of the substrate 110 is partially removed. More specifically, the cavity C may be disposed in a form in which the entire cavity C is buried inside the substrate 110, and accordingly, the substrate 110 may also be disposed between the cavity C and a resonator 120. The cavity C may be connected outwardly of the substrate 110 through an opening OP disposed at a position spaced apart from the resonator by a predetermined distance. Accordingly, the cavity C may be formed by partially removing the inside of the substrate 110 through the opening OP. The opening OP may be disposed around the resonator 120, and one or the plurality of openings OP may be disposed to be spaced apart from each other. The opening OP may be formed in a circular or rectangular hole shape, but is not limited to such a configuration.

A frame portion 127 may be provided along an edge of a region in which the active region, that is, a region in which the first electrode 121, the piezoelectric layer 123, and the second electrode 125 are disposed to all be overlapped, of the resonator 120. The frame portion 127 may have a thickness, which is greater than other portions of the second electrode 125. The frame portion 127 may function to confine resonance energy in the active region by reflecting lateral waves generated during resonance into the active region. Therefore, in the bulk-acoustic wave resonator of FIG. 15, the above-described insertion layer (170 in FIG. 2) may be omitted.

As described above, the bulk-acoustic wave resonator according to the various examples may be modified in various forms as necessary.

As set forth above, according to the various examples of the present disclosure, the bulk-acoustic wave resonator may increase Kt² and at the same time, maintain stable characteristics even under high voltage/high power conditions.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk-acoustic wave resonator, comprising:
a substrate; and
a resonator comprising a first electrode, a piezoelectric layer, and a second electrode sequentially stacked on the substrate,
wherein the piezoelectric layer is composed of aluminum nitride (AlN) containing scandium (Sc),
wherein a content of scandium in the piezoelectric layer is 10 wt % to 25 wt %, and
wherein the piezoelectric layer has a leakage current density of 1 μA/cm2 or less.

2. The bulk-acoustic wave resonator of claim 1, further comprising an insertion layer partially disposed in the resonator between the piezoelectric layer and the first electrode,
wherein the piezoelectric layer and the second electrode are both at least partially raised by the insertion layer.

3. The bulk-acoustic wave resonator of claim 2, wherein the resonator comprises a central portion and an extension portion disposed along a circumference of the central portion,
wherein the insertion layer is disposed only in the extension portion of the resonator,
wherein the insertion layer comprises an inclined surface with an increasing thickness as a distance from the central portion increases, and
wherein the piezoelectric layer comprises an inclined portion disposed on the inclined surface of the insertion layer.

4. The bulk-acoustic wave resonator of claim 3, wherein in a cross-section cut to cross the resonator, an end of the second electrode is disposed at a boundary between the central portion and the extension portion, or is disposed on the inclined portion of the piezoelectric layer.

5. The bulk-acoustic wave resonator of claim 4, wherein the piezoelectric layer comprises a piezoelectric portion disposed in the central portion and an extended portion extending outwardly of the inclined portion, and
wherein the second electrode comprises at least a portion disposed on the extended portion of the piezoelectric layer.

6. The bulk-acoustic wave resonator of claim 1, further comprising a Bragg reflective layer disposed below the resonator,
wherein the Bragg reflective layer comprises a first reflective layer having a first acoustic impedance and a second reflective layer having a second acoustic impedance lower than the first acoustic impedance, and the first reflective layer and the second reflective layer are alternately stacked.

7. The bulk-acoustic wave resonator of claim 1, wherein the substrate comprises a groove-shaped cavity formed on an upper surface thereof, and
the resonator is spaced apart from the substrate by a cavity.

8. The bulk-acoustic wave resonator of claim 1, wherein a cavity is disposed inside the substrate, and
wherein the cavity is connected to an outside of the substrate through an opening disposed around the resonator.

9. A method for manufacturing a bulk-acoustic wave resonator, comprising:
forming a piezoelectric layer by forming an AlScN thin film and performing a rapid thermal annealing (RTA) process on the AlScN thin film such that the piezoelectric layer has a leakage current density of 1 μA/cm2 or less; and
sequentially stacking a first electrode, the piezoelectric layer, and a second electrode on a substrate to form a resonator.

10. The method for manufacturing a bulk-acoustic wave resonator of claim 9, wherein forming the AlScN thin film is performed through a sputtering process using aluminum-scandium (AlSc) as a target.

11. The method for manufacturing a bulk-acoustic wave resonator of claim 9, wherein the RTA process is performed at a temperature of 500° C. or higher.

12. The method for manufacturing a bulk-acoustic wave resonator of claim 9, wherein the piezoelectric layer contains 10 wt % to 25 wt % of scandium (Sc).

13. The method for manufacturing a bulk-acoustic wave resonator of claim 9, further comprising forming an insertion layer disposed between the piezoelectric layer and the first electrode,
wherein at least a portion of the piezoelectric layer and the second electrode are both raised by the insertion layer.

14. The method for manufacturing a bulk-acoustic wave resonator of claim 13, wherein the insertion layer comprises an inclined surface, and
wherein in a cross-section cut to cross the resonator, at least a portion of an end of the second electrode is disposed to overlap the insertion layer.

15. The method for manufacturing a bulk-acoustic wave resonator of claim 14, wherein the resonator comprises a central portion and an extension portion disposed along a periphery of the central portion, and
wherein the end of the second electrode is disposed in the extension portion.
